(19) United States
(12) Patent Application Publication
(10) Pub. No.: US 2005/0272185 A1
(43) Pub. Date: Dec. 8, 2005

(54) Method of fabricating a semiconductor thin film and semiconductor thin film fabrication apparatus

(75) Inventors: Masanori Seki, Tenri-shi (JP); Yoshihiro Taniguchi, Nara-shi (JP); Tetsuya Inui, Nara-shi (JP)

Correspondence Address: EDWARDS & ANGELL, LLP, P.O. BOX 55874, BOSTON, MA, 02205, US

(73) Assignee: Sharp Kabushiki Kaisha

(21) Appl. No.: 11/147,641

(22) Filed: Jun. 7, 2005

(30) Foreign Application Priority Data
Jun. 7, 2004 (JP) 2004-168616(P)

(51) Int. Cl. H01L 21/00; H01L 21/84; C30B 1/00

(52) U.S. Cl. 438/149; 117/200

(57) ABSTRACT

A fabrication method of a semiconductor thin film including a polycrystalline semiconductor region by irradiating a precursor semiconductor thin film with at least two types of laser beams, and melting-recrystallizing the precursor semiconductor thin film, wherein the precursor semiconductor thin film is irradiated with a predetermined reference laser beam, and a radiation initiation time or power density of a laser beam is controlled according to change in reflectance of the site irradiated with the reference laser beam. A semiconductor thin film fabrication apparatus used in the fabrication method of present invention, wherein includes at least two light sources, a sensing unit, and a control unit. The crystals formed have no difference in the length of crystal caused by variation in the energy of each radiation.

This nonprovisional application is based on Japanese Patent Application No. 2004-168616 filed with the Japan Patent Office on Jun. 7, 2004, the entire contents of which are hereby incorporated by reference.

### BACKGROUND OF THE INVENTION

1. Field of the Invention

The present invention relates to a method of fabricating a semiconductor thin film utilizing an energy beam, particularly a laser beam, and a fabrication apparatus therefor.

2. Description of the Background Art

A polycrystalline thin film transistor corresponds to a transistor formed at a polycrystalline semiconductor thin film obtained by recrystallization of an amorphous semiconductor thin film. Such a polycrystalline thin film transistor is expected to allow high speed operation by virtue of the great charge carrier mobility, as compared to an amorphous thin film transistor corresponding to a transistor directly formed at an amorphous semiconductor thin film. The polycrystalline thin film transistor has the possibility of realizing large-scale integrated circuits on glass substrates as well as driving systems of liquid crystal devices.

The usage of a thin film transistor of crystalline silicon allows formation of a switching element for the pixel region in a liquid crystal display, for example, as well as a driving circuit for the pixel peripheral region and some peripheral circuits. Such elements and circuits can be formed on one substrate. Since it is therefore no longer necessary to mount an additional driver IC or driving circuit substrate in the display device, display devices can be produced at lower cost.

Another advantage of using a thin film transistor of crystalline silicon is the capability of reducing the dimension of the transistor. The switching elements constituting the pixel region become smaller to allow a higher aperture ratio for the display device. Thus, a display device of high luminance and high accuracy can be provided.

A polycrystalline semiconductor thin film is obtained by subjecting an amorphous semiconductor thin film produced through vapor deposition to thermal annealing for a long period of time below the strain point of glass (approximately 600-650° C.), or to optical annealing to receive light such as by a laser having a high energy density. Optical annealing is considered to be extremely effective for crystallization of a semiconductor thin film of high mobility since high energy can be applied to only the semiconductor thin film without raising the temperature of the glass substrate up to the strain point.

The aforementioned recrystallization technique employing an excimer laser is generally referred to as ELA (Excimer Laser Annealing), employed in industrial application as a laser crystallization technique superior in productivity. In accordance with the ELA, a glass substrate having an amorphous silicon thin film formed is heated to approximately 400° C. A linear excimer laser beam of approximately 200-400 mm in length and 0.2-1.0 mm in width is applied in pulsed radiation towards the amorphous silicon thin film on the glass substrate that is moved at a predetermined rate. By this method, a polycrystalline silicon thin film having an average grain size substantially equal to the thickness of the amorphous silicon thin film is obtained. The portion of amorphous silicon thin film irradiated with the excimer laser is melted, not thoroughly, but partially, in the direction of the thickness so as to leave an amorphous region. Therefore, a crystal nucleus is generated everywhere all over the laser-irradiated region plane, whereby silicon crystals will grow towards the top layer of the silicon thin film.

In order to obtain a display device of further higher performance, the crystal grain size of polycrystalline silicon must be increased and/or the orientation of the silicon crystal controlled. Various approaches have been proposed in order to obtain a polycrystalline silicon thin film having performance similar to that of monocrystal silicon. Among such various approaches, the technique of growing a crystal laterally (referred to as “super lateral growth” hereinafter) is known (refer to WO97/45827). Specifically, a silicon thin film is irradiated with a pulsed laser of an extremely small width such as several μm to be melted and agglomerated for crystallization throughout the entire region in the direction of thickness of the laser-irradiated region. Since the boundary between the molten portion and non-molten portion is perpendicular to the glass substrate plane, the crystals from the crystal nucleus generated thereat all grow laterally. As a result, needle-like crystals of uniform size, parallel to the glass substrate plane, are obtained by one pulse of laser radiation. Although the length of crystal formed by one pulse of laser radiation is approximately 1 μm, sequential emission of laser pulses so as to overlap with a portion of the previous needle-like crystal formed by laser radiation of the preceding pass allows succession of the already-grown crystal to result in a crystal grain of a longer needle shape.

In accordance with the super lateral growing method set forth above, the length of crystal grown through one pulse of laser radiation is approximately 1 μm. When a region having at least two times the length of crystal is melted as shown in FIGS. 6A and 6B, submicron crystals will be generated at the center portion of the molten region (FIG. 6B). Such submicron crystals are grown, not laterally, but vertically with respect to the substrate under the dominance of heat conduction towards the substrate. A needle-like crystal having a significantly increased length of crystal cannot be obtained by increasing the molten region. Therefore, pulse laser radiation must be repeated at a pitch as extremely small as approximately 0.4-0.7 μm in accordance with the super lateral growth. Achieving crystallization over the entire substrate employed in a display device and the like was therefore extremely time-consuming. There was a problem that the fabrication efficiency is extremely poor.

In view of forming a longer needle-shaped crystal through one pulse of laser radiation, various methods are proposed such as heating the substrate with a heater, heating the substrate or underlying film through a laser, or the like (for example, refer to Japanese Patent Laying-Open No. 06-291034). However, the method disclosed in Japanese Patent Laying-Open No. 06-291034 is directed to ZMR (Zone Melting Recrystallization), and crystal growth in the direction perpendicular to the substrate. Such methods are not directed to lateral growth.

A laser processing apparatus generally exhibits variation in the actual radiation energy with respect to the radiation energy of the set value. A crystal formed using such a laser processing apparatus will vary in grain size. This variation becomes more significant as the crystal grain size increases. Any difference in grain size induces variation in the characteristics of the semiconductor device. Specifically, if the crystal grain size differs depending upon where the semiconductor device is fabricated, the number of grain boundaries in the moving direction of electrons will differ with respect to a certain predetermined channel length. As a result, variation is exhibited in the characteristics of semiconductor devices such as the mobility.

For the purpose of maintaining a constant temperature at the surface of the semiconductor thin film, there is proposed the technique of controlling the laser light source by sensing change in temperature at the surface of the semiconductor substrate (for example, refer to Japanese Patent Laying-Open No. 04-338631). The approach disclosed in Japanese Patent Laying-Open No. 04-338631 is directed to sensing the temperature of the laser-irradiated portion using a radiation thermometer to modulate the laser beam according to the sensed result. It is to be noted that even the fastest response rate of a radiation thermometer is on the order of several milliseconds. Therefore, there was a problem that it cannot be applied to measuring the temperature of the laser processing location using a laser beam that has a pulse width on the order of several hundred nanoseconds or microseconds.

### SUMMARY OF THE INVENTION

In view of the foregoing, an object of the present invention is to provide a method of fabricating a semiconductor thin film with no difference in the length of formed crystals caused by variation in the energy of each radiation, and a fabrication apparatus therefor.

According to an aspect of the present invention, a fabrication method of a semiconductor thin film having a polycrystalline semiconductor region includes the steps of irradiating a precursor semiconductor thin film with at least two types of laser beams, and melting-recrystallizing the precursor semiconductor thin film, wherein the precursor semiconductor thin film is irradiated with a predetermined reference laser beam, and a radiation initiation time or power density of a laser beam is controlled according to change in reflectance of the site of the precursor semiconductor thin film irradiated with the reference laser beam.

Since the length of crystals formed by each radiation is set uniformly in accordance with the present invention, a method of fabricating in stability a semiconductor thin film including a polycrystalline semiconductor region having the length of crystal increased significantly in the lateral growing distance, and a fabrication apparatus therefor can be provided. By the fabrication method and fabrication apparatus of the present invention, a TFT (Thin Film Transistor) having the performance greatly improved as compared to a conventional one can be fabricated in stability. Since the feeding pitch in super lateral growth can be increased significantly in accordance with the fabrication method of the present invention, the crystallization processing time can also be reduced significantly.

The at least two types of laser beams preferably includes a first laser beam having a wavelength that can be absorbed by the precursor semiconductor thin film and energy that can melt the precursor semiconductor thin film, and a second laser beam having a wavelength and energy that can control the process of recrystallization of the molten precursor semiconductor thin film.

Preferably in the fabrication method of a semiconductor thin film of the present invention, the reference laser beam is the second laser beam. The radiation initiation time or power density of the first or second laser beam is controlled according to change in reflectance of the second laser beam to melting-recrystallize the precursor semiconductor thin film.

Preferably in the fabrication method of a semiconductor thin film of the present invention: the first laser beam is emitted according to change in the power density of reflected light of the second laser beam; the power density of the first laser is controlled beam according to change in the power density of reflected light of the second laser beam; or the power density of the second laser beam is controlled according to change in the power density of reflected light of the second laser beam.

Preferably in the fabrication method of a semiconductor thin film of the present invention, the first laser beam has a wavelength in the ultraviolet range or visible range, and the second laser beam has a wavelength in the visible range or infrared range.

The second laser beam employed in the present invention preferably has a wavelength in the range of 9 to 11 μm.

The crystal grown during recrystallization in the fabrication method of a semiconductor thin film of the present invention is preferably grown substantially parallel to the semiconductor thin film substrate plane.

According to another aspect of the present invention, a semiconductor thin film fabrication apparatus includes at least two laser light sources that can irradiate a precursor semiconductor thin film with at least two types of laser beams, a sensing unit that can sense change in reflectance of a site of the precursor semiconductor thin film irradiated with a predetermined reference laser beam, and a control unit that can control a radiation initiation time or power density of a laser beam according to change in reflectance of a site of the precursor semiconductor thin film irradiated with the reference laser beam.

Preferably in the semiconductor thin film fabrication apparatus of the present aspect, the at least two laser light sources include a first laser light source emitting a first laser beam having a wavelength that can be absorbed by the precursor semiconductor thin film and energy that can melt the precursor semiconductor thin film, and a second laser light source emitting a second laser beam having a wavelength and energy that can control the process of recrystallization of the molten precursor semiconductor thin film. The sensing unit senses change in reflectance of a site irradiated with the second laser beam as the reference laser beam. The control unit controls the radiation initiation time or power energy of the first or second laser beam according to change in reflectance of a site of the precursor semiconductor thin film irradiated with the second laser beam.

The sensing unit is preferably a sensor that can sense change in power density of reflected light of the second laser beam at the site irradiated with the second laser beam, more preferably an optical sensor capable of such sensing.

Preferably in the semiconductor thin film fabrication apparatus of the present invention, the first laser light source emits a first laser beam having a wavelength in the ultra violet range or visible range, and the second light source emits a second laser beam having a wavelength in the visible range or infrared range.

The second laser beam emitted from the second laser light source in the semiconductor thin film fabrication apparatus of the present invention preferably has a wavelength in the range of 9 to 11 μm.

The crystal grown during recrystallization by the semiconductor thin film fabrication apparatus of the present invention is preferably grown substantially parallel to the semiconductor thin film substrate plane.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a graph for describing a first method of fabricating a semiconductor thin film of the present invention.

FIG. 2 is a graph representing results of experiments carried out when melting-recrystallization is conducted in a manner similar to that of the first method, wherein a substrate is irradiated with the second laser beam, and then irradiated with the first laser beam at an elapse of a predetermined time, with the exception of not using the sensed results of the temperature of the substrate.

FIG. 3 is a graph to describe a third method of fabricating a semiconductor thin film of the present invention.

FIG. 4 schematically shows a preferable example of a substrate composite 5 suitable for usage in the fabrication method of a semiconductor thin film in the present invention.

FIG. 5 schematically shows a preferable example of a semiconductor thin film fabrication apparatus 10 of the present invention.

FIGS. 6A and 6B are diagrams to describe a conventional method of fabricating a semiconductor thin film.

### DESCRIPTION OF THE PREFERRED EMBODIMENTS

The fabrication method of the present invention is based on a method of fabricating a semiconductor thin film including a polycrystalline semiconductor region by irradiating a precursor semiconductor thin film with at least two types of laser beams, and melting-recrystallizing the precursor semiconductor thin film. At least two types of laser beams are employed in the present invention. The type of the laser beam is not particularly limited, and may be any type as long as a precursor semiconductor thin film is melting-recrystallized through irradiation with at least one of the two types of laser beams to result in formation of a polycrystalline semiconductor region. Preferably, the laser beams of the present invention include a first laser beam having a wavelength that can be absorbed by a precursor semiconductor thin film, and that can melt the precursor semiconductor thin film, and a second laser beam having a wavelength and energy that can control the process of recrystallization of the molten precursor semiconductor thin film.

An important feature in the fabrication method of a semiconductor thin film of the present invention is that the radiation initiation time or power density of the laser beam is controlled according to change in reflectance of a site of the precursor semiconductor thin film irradiated with a predetermined reference laser beam. As used herein, “reference laser beam” is a laser beam determined arbitrarily in advance from the at least two types of laser beams. The reference laser beam is emitted to a precursor semiconductor thin film prior to irradiation of the precursor semiconductor thin film with a laser beam for melting-recrystallization. When the first laser beam and the second laser beam are employed, the second laser beam may be used as the reference laser beam. Alternatively, another laser beam (third laser beam) may be applied as the reference laser beam.

In the present invention, the laser beam directed to melting-recrystallization of a precursor semiconductor thin film is controlled according to change in reflectance of a site of the precursor semiconductor thin film irradiated with the reference laser beam. As used herein, “change in reflectance” refers to “change in the power density of reflected light” of the reference laser beam on the precursor semiconductor thin film. “Change in the power density of reflected light” refers to change in the absolute value of the power density of reflected light, or change in the ratio of power density referenced to the power density of a predetermined period of time. Since there is the possibility of variation in the power density of the reference laser beam, it is most preferable to have the radiation initiation time or power density of the laser beam directed to melting-recrystallization of the precursor semiconductor thin film controlled according to change in the ratio of the power density of the reference laser beam on the precursor semiconductor thin film.

In the present invention, the radiation initiation time of the laser beam (timing of irradiation) or the power density of the laser beam for melting-recrystallization is controlled according to change in reflectance of a site of the precursor semiconductor thin film irradiated with the reference laser beam. In the case where “the at least two types of laser beams” include the first laser beam and the second laser beam set forth above, the subject of control according to change in reflectance of the reference laser beam may be either the first laser beam or second laser beam.

In the fabrication method of the semiconductor thin film of the present invention, the crystal grown during recrystallization is preferably grown substantially parallel to the plane of the semiconductor thin film substrate. Since the length of crystals formed by each radiation is set uniformly in accordance with the present invention, a method of fabricating in stability a semiconductor thin film including a polycrystalline semiconductor region having the length of crystal increased significantly in the lateral growing distance can be provided. By the fabrication method of the present invention, a TFT having the performance greatly improved as compared to a conventional one can be fabricated in stability. Since the feeding pitch in super lateral growth can be increased significantly in accordance with the fabrication method of the present invention, the crystallization processing time can also be reduced significantly.

The at least two types of laser beams preferably includes a first laser beam having a wavelength that can be absorbed by the precursor semiconductor thin film and energy that can melt the precursor semiconductor thin film, and a second laser beam having a wavelength and energy that can control the process of recrystallization of the molten precursor semiconductor thin film. In the fabrication method of a semiconductor thin film of the present invention, the radiation initiation time or power density of the first or second laser beam is controlled according to change in reflectance of the second laser beamidentified as the reference laser beam to melting-recrystallize the precursor semiconductor thin film. There is an advantage of simplifying the structure of the apparatus by using the second laser beam as the reference laser beam instead of using a third laser beam as a reference laser beam.

In view of the fabrication method of a semiconductor thin film of the present invention set forth above, any one of the following approaches of (1)-(3) is particularly favorable.
(1) Emitting the first laser beam according to change in the power density of the reflected light of the second laser beam (referred to as “first method” hereinafter);
(2) Controlling the power density of the first laser beam according to change in the power density of the reflected light of the second laser beam (referred to as “second method” hereinafter); and
(3) Controlling the power density of the second laser beam according to change in the power density of reflected light of the second laser beam (referred to as “third method” hereinafter).

Each of these methods will be described in detail hereinafter.

(1) First Method

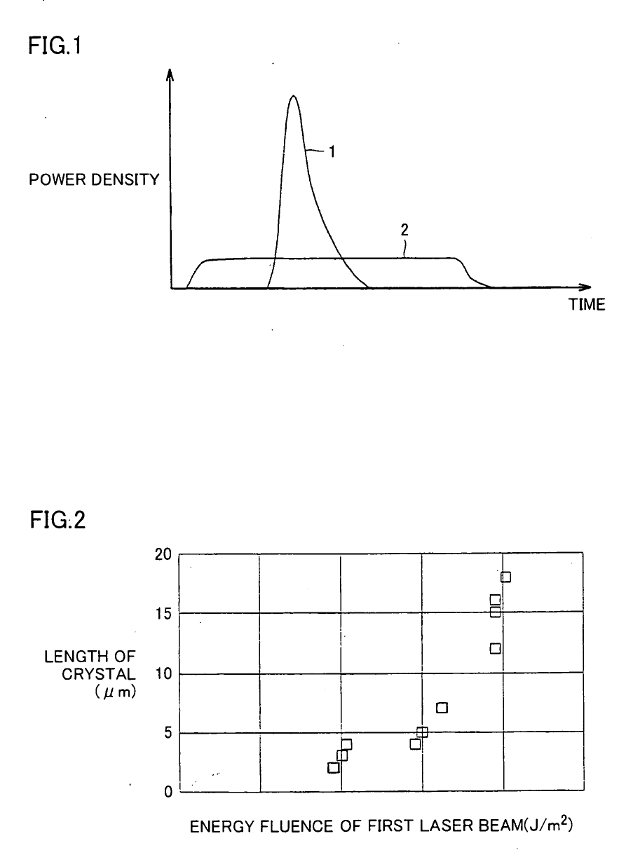

FIG. 1 is a graph to describe the first method of fabricating a semiconductor thin film of the present invention. The power density is plotted along the ordinate, and time is plotted along the abscissa. In the graph of FIG. 1, designation 1 represents the waveform of the first laser beam emitted, whereas designation 2 represents the waveform of the second laser beam emitted. FIG. 2 is a graph representing the results of experiments carried out when the second laser beam is emitted, and then the first laser beam is emitted without sensing change in the reflectance of the second laser beam. In accordance with the first fabrication method of the present invention, the second laser beam is used as the reference laser beam to be emitted to a precursor semiconductor thin film substrate having an amorphous semiconductor region. Then, the power density of reflected light of the second laser beam on the precursor semiconductor thin film is sensed, followed by emission of the first laser beam when the sensed power density attains a predetermined value. Thus, a needle-like crystal having the length of crystal increased significantly can be obtained by the first method.

Upon emitting the second laser beam having a wavelength and energy that can control the process of recrystallization of a molten precursor semiconductor thin film onto a precursor semiconductor thin film having an amorphous semiconductor region, the precursor semiconductor thin film will be heated. Since the energy of the second laser beam varies at each radiation, the temperature of the precursor semiconductor thin film and the precursor semiconductor thin film substrate at the time of irradiation with the first laser beam differs for each radiation of the second laser beam even if the elapsed time from emission of the second laser beam to emission of the first laser beam is identical. Accordingly, the length of crystal differed at each radiation of the second laser beam, as shown in FIG. 2, under laser processing conditions directed to increasing the length of lateral crystal significantly even if the fluence energy of the first laser beam is identical. Specifically, even if the values of P×t1 based on P (t)=P for a radiation laser beam having a rectangular waveform and the values of ∫₀^{t1} P(t)dt for a radiation laser beam having a waveform other than a rectangle (where P (t) is the power density and t 1 is the radiation time) are identical, the length of crystal differed at each radiation of the second laser beam. In view of the foregoing, the first method of the present invention is directed to sensing change in the temperature of the precursor semiconductor thin film caused by irradiation with the second laser beam through change in the power density of the relevant second laser beam, and then emitting the first laser beam when the precursor semiconductor thin film or precursor semiconductor thin film substrate reaches a predetermined temperature. Accordingly, the crystal is less susceptible to variation in the energy at each emission of the second laser beam, allowing a stable length of crystal for each radiation.

The temperature change of the precursor semiconductor thin film caused by irradiation with the second laser beamidentified as the reference laser beam can be sensed through the power density of reflected light of the second laser beam. Semiconductor materials and metal materials generally have a predetermined reflectance with respect to light of each wavelength. This is because the reflectance depends on the refractive index at each wavelength of each material. The refractive index has dependency on the temperature of the material. Therefore, the reflectance exhibits temperature dependency. The inventors obtained the results that the reflectance of a laser beam having a wavelength of 10.6 μm from a precursor semiconductor thin film including an amorphous semiconductor region is approximately 16%, approximately 19%, and approximately 20% at room temperature (25° C.), approximately 300° C., and approximately 600° C., respectively. The reflectance was obtained as set forth below. A laser beam having a wavelength of approximately 10.6 μm corresponding to a level that induces almost no elevation in temperature at the precursor semiconductor thin film substrate including an amorphous semiconductor region was applied towards the substrate obliquely. The pulse energy before and after reflection from the substrate was measured by an energy meter. The reflectance was obtained by the ratio of the measured value after reflection to the measured value before reflection. The reflectance corresponding to the temperatures other than the room temperature was obtained based on measurements while heating the substrate with a heater. The film structure of the semiconductor thin film substrate employed in the measurement was formed of a glass substrate, a 1000 Å silicon oxide film (SiO₂) and a 450 Å amorphous silicon film (a-Si). The power density of the second laser beam at respective temperatures can be obtained by (power density of second laser beam)×(reflectance at each temperature). Assuming that the second laser beam has a power density of 8100 J/m² and a pulse width (radiation time) of 130 μsec, the sensed power density of reflected light of the second laser beam is 10.0 MW/m², 11.9 MW/m², and 12.5 MW/m² at room temperature, 300° C., and 600° C., respectively. It is therefore appreciated that, when the first laser beam is to be emitted when the temperature of the precursor semiconductor thin film is 300° C., the first laser beam should be emitted upon sensing change in power density of the second laser beam from 10.0 MW/m² to 11.9 MW/m². When the temperature of the precursor semiconductor thin film is in the vicinity of 300° C., the power density of reflected light varies 0.03 MW/m² for every 10° C. change in temperature of the precursor semiconductor thin film. It is desirable to control the timing of emitting the first laser beam upon identifying this change of 0.03 MW/m².

In the first method, the fluence energy (power density×radiation time) of the first laser beam and the second laser beam takes constant values. In this case, the energy fluence of the first laser beam is selected from the range of preferably 1500 to 3500 J/m², further preferably 2500 to 3000 J/m². This is because an energy fluence less than 1500 J/m² for the first laser beam tends to disable formation of a crystal grain having a long crystal length, and an energy fluence exceeding 3500 J/m² for the first laser beam tends to cause ablation of the Si thin film. When the pulse width of the second laser beam is 130 psec, the energy fluence of the second laser beam is selected preferably from the range of 7500 to 10000 J/m², more preferably from the range of 8000 to 9000 J/m². This is because an energy fluence less than 7500 J/m² for the second laser beam tends to disable formation of a crystal grain having a long crystal length, and an energy fluence exceeding 10,000 J/m² for the second laser beam tends to cause ablation of the Si thin film, as well as deformation and/or damage of the semiconductor thin film substrate by the second laser beam.

(2) Second Method

In accordance with the second method of the present invention, the precursor semiconductor thin film is irradiated with the second laser beamidentified as the reference laser beam as shown in FIG. 1, and then irradiated with the first laser beam at an elapse of a predetermined time. The second method differs from the first method set forth above in that the power density of reflected light of the second laser beam from the precursor semiconductor thin film is sensed, and the power density of the first laser beam is controlled according to the power density sensed immediately before emission of the first laser beam. Specifically, the power density of the first laser beam is increased when the sensed power density of reflected light of the second laser beam is smaller than a predetermined value. In contrast, when the sensed power density of the reflected light is larger than the predetermined value, the power density of the first laser beam is reduced. It is appreciated from FIG. 2 that the length of crystal increases in accordance with a higher energy fluence of the first laser beam. By controlling the power density of the first laser beam in accordance with variation in the power density of reflected light of the second laser beam through the second method, a semiconductor thin film having a desired length of crystal can be fabricated.

In the second method, the point in time of initiating radiation of the first laser beam is fixed. The radiation initiation time of the first laser beam is determined depending upon the desired length of crystal, the power density of the first laser beam, the power density of the second laser beam, and the pulse width of the second laser beam. If radiation is initiated before elapse of the predetermined period of time, the length of crystal tends to become shorter than the desired length. If radiation is initiated way after elapse of time corresponding to the pulse width of the second laser beam, the length of crystal also tends to become shorter than the desired length

For example, when the desired length of crystal is at least 10 μm, the energy fluence of the first laser beam is 3000 J/m², the energy fluence of the second laser beam is 8100 J/m², and the pulse width (radiation time) is 130 μsec, the radiation initiation time of the first laser beam is preferably in the range of 110-130 μsec, more preferably in the range of 120-130 μsec from the radiation initiation time of the second laser beam. This is because, if radiation of the first laser beam is initiated at a point in time before 110 μsec from the initiation of the second laser beam radiation, the length of crystal is liable to become shorter than the desired length. Furthermore, if radiation of the first laser beam is initiated at the point in time after 130 psec from the initiation of the second laser beam radiation, the length of crystal is liable to become shorter than the desired length.

(3) Third Method

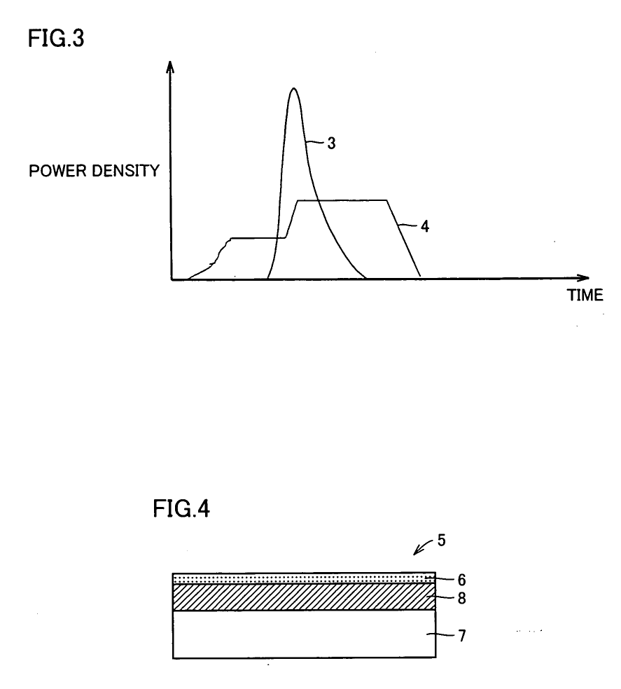

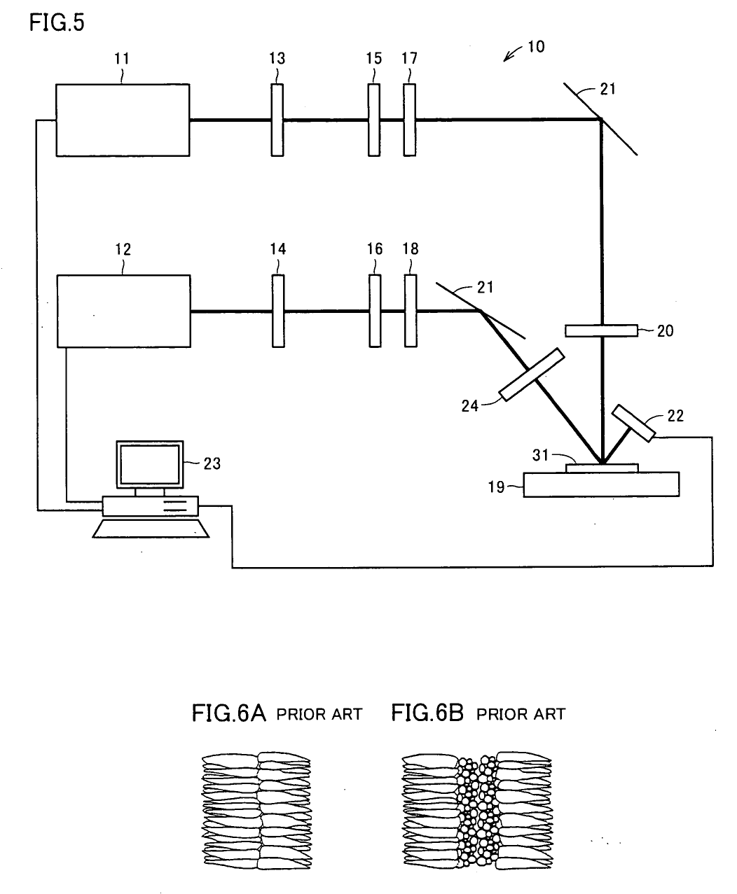

FIG. 3 is a graph to describe the third method of fabricating a semiconductor thin film of the present invention. The power density is plotted along the ordinate, and time is plotted along the abscissa. In the graph of FIG. 3, designation 3 indicates the radiation waveform of the first laser beam, and designation 4 indicates the radiation waveform of the second laser beam. In the third method of the present, the precursor semiconductor thin film is irradiated with the second laser beamidentified as the reference laser beam as shown in FIG. 3, and then irradiated with the first laser beam at an elapse of a predetermined time. The third method differs from the second method set forth above in that the power density of reflected light of the second laser beam from the precursor semiconductor thin film is sensed, and the power density of the second laser beam is controlled according to the power density sensed immediately before emission of the first laser beam. Specifically, the power density of the second laser beam is increased when the sensed power density of reflected light of the second laser beam is smaller than a predetermined value. When the power density of reflected light is larger than the predetermined value, the power density of the second laser beam is reduced. Microstructure crystals as shown in FIG. 6B are formed at the center area of the laser radiation region since lateral growth is suppressed by the heat conduction in the direction of the substrate. Therefore, in order to suppress generation of microstructure crystals formed at the center area of the laser radiation region and further increase the distance of lateral growth, agglomeration at the center area of the laser radiation region is to be retarded. In accordance with the third method, the process of recrystallization of molten silicon can be controlled (adjustment of cooling rate) by controlling the power density of the second laser beams towards molten silicon. A stable length of crystal can be achieved at each radiation.

Likewise the second method set forth above, the point in time of initiating radiation of the laser beam is fixed in the third method. The point in time of initiating radiation of the first laser beam is determined depending upon the desired length of crystal, the power density of the first laser beam, the power density of the second laser beam, and the pulse width of the second laser beam. If radiation is initiated before elapse of the predetermined period of time, the length of crystal tends to become shorter than the desired length. If radiation is initiated way after elapse of time corresponding to the pulse width of the second laser beam, the length of crystal also tends to become shorter than the desired length.

For example, when the desired length of crystal is at least 10 μm, the energy fluence of the first laser beam is 3000 J/m², the energy fluence of the second laser beam is 8100 J/m², and the pulse width (radiation time) is 130 μsec, the radiation initiation time of the first laser beam is preferably at a point of time in the range of 110-130 μsec, and more preferably in the range of 120-130 μsec, from the initiation of the second laser beam radiation. This is because, if radiation of the first laser beam is initiated at a point in time before 110 μsec from the initiation of the second laser beam radiation, the length of crystal is liable to become shorter than the desired length. Furthermore, if radiation of the first laser beam is initiated at a point in time after 130 μsec from the initiation of the second laser beam radiation, the length of crystal is liable to become shorter than the desired length.

In the case where at least two types of laser beams include the first laser beam and the second laser beam set forth above in the fabrication method of a semiconductor thin film of the present invention, it is preferable to employ a first laser beam having a wavelength in the ultraviolet range since great energy can be applied to the thin film in an extremely short period of time in the order of ns to μs, and light of the ultraviolet range can be absorbed favorably by a silicon thin film. As used herein, “wavelength in the ultraviolet range” refers to a wavelength of at least 1 nm and less than 400 nm. Various solid lasers such as an excimer laser and YAG laser can be employed for the first laser beam. In particular, an excimer laser having the wavelength of 308 nm is preferable.

In the case where t at least two types of laser beams include the first laser beam and the second laser beam set forth above, the process of recrystallization of molten silicon must be controllable through the second laser beam. In other words, it is required that the second laser beam can heat the precursor semiconductor thin film substrate having an amorphous semiconductor region, and be absorbable by molten silicon. Therefore, a laser beam having a wavelength in the visible range or infrared range (a laser beam having a wavelength from the visible range to infrared range) is preferable. As used herein, “wavelength in the visible range” refers to a wavelength of at least 400 nm and less than 750 nm. “Wavelength in the infrared range” refers to a wavelength of at least 750 nm and not more than 1 mm. Particularly suitable for such a second laser beam is the beam of a YAG laser having the wavelength of 532 nm, a YAG laser having the wavelength of 1064 nm, or a CO₂ laser having the wavelength in the range of 9-11 μm (particularly, wavelength of 10.6 μm). The absorptance of liquid silicon with respect to light of 532 nm and 1064 nm in wavelength is approximately 60% (refer to Japanese Patent Laying-Open No. 05-235169). The absorptance of liquid silicon with respect to light of 10.6 μm in wavelength is approximately 10-20% (experimental results carried out by inventors of present invention). Therefore, a laser of 532 nm and 1064 nm in wavelength having high absorptance with respect to molten silicon is to be employed in the third method.

The precursor semiconductor thin film employed in the fabrication method of the present invention is not particularly limited, and an arbitrary semiconductor material can be employed as long as it is an amorphous semiconductor or crystalline semiconductor. As a specific example of the material of the precursor semiconductor thin film, a material including amorphous silicon such as hydrated amorphous silicon (a-Si: H) is preferable due to the fact that it is conventionally used in the fabrication of a liquid crystal display element and that fabrication is feasible. Such materials include, but not limited to, materials containing amorphous silicon. A material containing polycrystalline silicon inferior in polycrystallinity, or a material containing microcrystal silicon may be used. Furthermore, the precursor semiconductor thin film is not limited to a material formed only of silicon. A material with silicon as the main component and including other elements such as germanium may be employed. For example, addition of germanium allows arbitrary control of the forbidden band width of the precursor semiconductor thin film.

The thickness of the precursor semiconductor thin film is preferably, but not limited to, 30-200 nm. This is because, if the precursor semiconductor thin film is too thin, it may become difficult to grow a film with uniform thickness. Furthermore, if the precursor semiconductor thin film is too thick, the time required for growing the film may be increased.

The precursor semiconductor thin film is applied to the fabrication method of the present invention in morphology of generally a structure formed on an insulative substrate (referred to as “substrate composite” in the present specification). FIG. 4 schematically shows a preferable example of a substrate composite 5 that can be suitably employed in the fabrication method of the semiconductor thin film in the present invention. In such a substrate composite 5, a precursor semiconductor thin film 6 is formed on an insulative substrate 7 by, for example, CVD (Chemical Vapor Deposition).

A substrate well known in the field of art formed of a material including glass, quartz, or the like can be suitably employed as insulative substrate 7. It is desirable to use a glass insulative substrate from the standpoint of economic perspective and ease in fabricating a large-area insulative substrate. The thickness of the insulative substrate is preferably, but not limited to, 0.5-1.2 mm. This is because, if the thickness of the insulative substrate is less than 0.5 mm, the insulative substrate may easily crack. Further, it may become difficult to fabricate a substrate of high planarity. If the thickness of the insulative substrate exceeds 1.2 mm, the substrate may become too thick or too heavy when a display device is provided.

In substrate composite 5, precursor semiconductor thin film 6 is preferably formed on insulative substrate 7 with a buffer layer 8 therebetween. The provision of buffer layer 8 suppresses the heat effect of molten precursor semiconductor thin film 6 on the glass insulative substrate during melting-recrystallization through a laser beam. Furthermore, impurity diffusion from insulative substrate 7 that is a glass substrate into precursor semiconductor thin film 6 can be prevented. Buffer layer 8 is not particularly limited, and can be formed by, for example, CVD, or the like using a material conventionally employed in the field of art such as silicon oxide, silicon nitride, and the like. The thickness of buffer layer 8 is preferably, but not particularly limited to, 100-500 nm. This is because, if the buffer layer is too thin, the effect of preventing impurity diffusion may be insufficient. Furthermore, if the buffer layer is too thick, the time required for growing the film may be too time-consuming.

The present invention also provides a semiconductor thin film fabrication apparatus. The semiconductor thin film fabrication apparatus of the present invention includes at least two laser light sources that can irradiate a precursor semiconductor thin film with at least two types of laser beams, a sensing unit that can sense change in reflectance of a site of the precursor semiconductor thin film irradiated with a predetermined reference laser beam, and a control unit that can control the radiation initiation time or power density of a laser beam according to change in reflectance of a site of the precursor semiconductor thin film irradiated with the reference laser beam. In the semiconductor thin film fabrication apparatus of the present invention, the terms of “at least two types of laser beams”, “reference laser beam”, “change in reflectance” and the like are as set forth above in the description of the fabrication method of a semiconductor thin film. The fabrication method of a semiconductor thin film of the present invention set forth above can be suitably carried out by using the semiconductor thin film fabrication apparatus. The crystal grown during recrystallization is preferably grown substantially parallel to the plane of the semiconductor thin film substrate. In accordance with the semiconductor thin film fabrication apparatus of the present invention, a semiconductor thin film including a polycrystalline semiconductor region in which the length of crystal has the lateral growing distance increased significantly can be fabricated in stability with no difference in the length of formed crystals caused by variation in the energy of each radiation. As a result, a TFT having the performance improved greatly as compared to a conventional one can be fabricated in stability.

FIG. 5 schematically shows a preferable example of a semiconductor thin film fabrication apparatus 10 of the present invention. The semiconductor thin film fabrication apparatus 10 of the present invention basically includes at least two laser light sources corresponding to a first laser light source (first laser oscillator) 11 emitting a first laser beam having a wavelength that can be absorbed by a precursor semiconductor thin film and energy that can melt the precursor semiconductor thin film, and a second laser light source (second laser oscillator) 12 emitting a second laser beam having a wavelength and energy that can control the process of recrystallization of molten precursor semiconductor thin film, as well as a sensing unit 22 that can sense change in reflectance of a site irradiated with the second laser beamidentified as the reference laser beam, and a control unit 23 that can control the radiation initiation time or power density of the first or second laser beam according to change in reflectance of a site of the precursor semiconductor thin film irradiated with the second laser beam. Semiconductor thin film fabrication apparatus 10 of FIG. 5 can be implemented suitably by appropriate combining a laser light source, various optical components, a sensing unit and a control unit well-known and used conventionally in the field of art.

Semiconductor thin film fabrication apparatus 10 of FIG. 5 is configured such that the first laser beam emitted from first laser light source 11 passes through an attenuator 13, a uniform radiation optical system 15, a mask 17, and an imaging lens 20 to be impinged on a substrate composite 31. Substrate composite 31 is mounted on a stage 19 that can move in the X-Y direction at a predetermined speed.

First laser light source 11 is not particularly limited, as long as it is capable of emitting a laser beam having a wavelength that can be absorbed by a precursor semiconductor thin film and that can melt the precursor semiconductor thin film. From the standpoint of applying great energy to the thin film in an extremely short period of time in the order of ns to μs, and favorable absorption of light in the ultraviolet range by the silicon thin film, first laser light source 11 is preferably a light source that can emit a laser beam having a wavelength of the ultraviolet range. For example, ultraviolet lasers such as an excimer laser and YAG laser can be employed as the first laser light source. Particularly, a laser light source that can emit an excimer laser beam of 308 nm in wavelength is preferable. Also, the first laser light source preferably emits a pulsive energy beam.

The laser beam emitted from first laser light source 11 is attenuated to a predetermined luminous energy by attenuator 13 located at the path of the first laser beam to have the power density adjusted. Then, the first laser beam has the power density distribution rendered uniform by uniform radiation optical system 15 to be shaped to an appropriate dimension, and applied evenly on the pattern formation face of mask 17. The image of mask 17 is formed on substrate composite 31 by imaging lens 20 at a predetermined magnification (for example, ¼). Mirror 21 provided at the path of the first laser beam to reflect the laser beam is not limited in location and number, and can be arranged appropriately according to the design of the optical system and configuration of the apparatus.

In semiconductor thin film fabrication apparatus 10 of FIG. 5, the second laser beam emitted from second light source 12 passes through an attenuator 14, a uniform radiation optical system 16, a mask 18, and an imaging lens 24 constituting an optical path of the second laser beam to be applied on substrate composite 31.

Second laser light source 12 is not particularly limited, as long as it is capable of emitting a laser beam having a wavelength and energy that can control the process of recrystallization of molten precursor semiconductor thin film. From the standpoint of controlling the process of recrystallization of molten silicon and heating the precursor semiconductor thin film, as well as favorable absorption by molten silicon, second laser light source 12 is preferably a light source that can emit a laser beam having a wavelength in the visible range or infrared range (a laser beam having a wavelength from the visible range to infrared range). For example, a YAG laser having the wavelength of 532 nm, a YAG laser having the wavelength of 1064 nm, or a CO₂ laser having the wavelength in the range of 9-11 μm (particularly, wavelength of 10.6 μm) is preferable.

The laser beam emitted from second laser light source 12 is attenuated to a predetermined luminous energy by attenuator 14 located at the path of the second laser beam to have the power density adjusted. Then, the second laser beam has the power density distribution rendered uniform by uniform radiation optical system 16 to be shaped to an appropriate dimension, and applied evenly on the pattern formation face of a mask 18. The image of mask 18 is formed on substrate composite 31 by imaging lens 24 at a predetermined magnification. Mirror 21 provided at the path of the second-laser beam to reflect the laser beam is not limited in location and number, and can be arranged appropriately according to the design of the optical system and configuration of the apparatus.

Sensing unit 22 is configured to measure the power density of reflected light of the second laser beam on the precursor semiconductor thin film. Sensing unit 22 is not particularly limited, as long as it is capable of measuring the power density. Well-known sensing means conventionally used such as an optical sensor, a pyroelectric sensor, and the like may be used. Particularly, an optical sensor that is superior in high response is preferable.

The optical sensor is not particularly limited, and an optical sensor having the photosensitive unit formed of Si may be used. When a YAG laser of 1064 nm in wavelength is employed as the second light source, the photosensitive unit is preferably formed of AgOCs or InGaAs. When a CO₂ laser of 10.6>m in wavelength is employed as the second light source, the photosensitive unit is preferably formed of HdCdZnTe.

It is also preferable to employ an optical sensor configured to output the measured result as a voltage value to control unit 23. The optical sensor preferably includes an attenuator optical system (not shown) by virtue of possessing predetermined laser resistance. Furthermore, the control unit preferably includes a control circuit in which the voltage value that is the value output from the optical sensor varies by at least the width of oscillation of the noise component for every 10° C. change in temperature of semiconductor substrate 31.

Control unit 23 is not particularly limited, as long as it can control the radiation initiation time or power density of the first or second laser beam according to change in reflectance of a site of the precursor semiconductor thin film irradiated with the second laser beam, sensed by sensing unit 22. Specifically, control unit 23 employs a different configuration depending upon which of the first to third methods of fabricating a semiconductor thin film of the present invention set forth above is applied. For example, the control unit in a semiconductor thin film fabrication apparatus corresponding to the first method is realized to control the timing of emitting the first laser beam according to change in the power density of reflected light of the second laser beam sensed by the sensing unit. The control unit in a semiconductor thin film fabrication apparatus corresponding to the second method is realized to control the power density of the first laser beam according to change in the power density of reflected light of the second laser beam sensed by the sensing unit. The control unit in a semiconductor thin film fabrication apparatus corresponding to the third method is realized to control the power density of the second laser beam according to change in the power density of reflected light of the second laser beam sensed by the sensing unit. The control unit set forth above can be realized by employing or combining appropriately well-known control means. Control unit 23 may be implemented to conduct control of the position of the stage not shown, store the laser radiation target position, control the temperature in the apparatus, and control the atmosphere in the apparatus.

Although an optical sensor that senses the power density of reflected light of the second laser beam is taken as an example as the sensing unit, the sensing unit in the semiconductor thin film fabrication apparatus of the present invention may be any sensing unit that can sense the change in reflectance of a site on the precursor semiconductor thin film irradiated with the reference laser beam. The apparatus of the present invention may further include a laser light source that can emit a third laser beam (third laser light source). Using this third laser beam as the reference laser beam, an optical sensor can be employed capable of sensing corresponding to the wavelength of the third laser beam. In this case, a laser beam having a wavelength that exhibits greater change in reflectance with respect to change in temperature of the precursor semiconductor thin film is used. For example, comparison was conducted through experiments between a YAG laser having a wavelength of 532 nm and a carbon dioxide gas laser having a wavelength of 10.6 μm employed as the reference laser beam. The inventors of the present invention identified that, when the temperature of the precursor semiconductor thin film is in the vicinity of 300° C., the change in reflectance for every 10° C. change in temperature at the precursor semiconductor thin film substrate was 0.07% and 0.09%, respectively. Since temperature difference can be sensed more easily if the change in reflectance per unit temperature is greater, a carbon dioxide gas laser is more preferable. In this case, an optical sensor having the photosensitive unit formed of HdCdZnTe is preferably used.

The present invention will be described in further detail based on examples set forth below. It is to be understood that the present invention is not limited to these examples.

### EXAMPLE 1

Using a semiconductor thin film fabrication apparatus configured as shown in FIG. 5, a second laser beam shaped into a rectangle such that the size on the substrate plane is 5.5 mm×5.5 mm was directed obliquely onto a substrate composite, as the reference laser beam. The first laser beam shaped into a rectangle such that the size on the substrate plane is 40 μm×500 μm in accordance with change of the power density of reflected light of the second laser beam was directed perpendicularly. An excimer laser having a wavelength of 308 nm emitting pulsive energy was employed for the first laser beam. A carbon dioxide gas laser having a wavelength of 10.6 μm emitting pulsive energy was employed for the second laser beam. The energy fluence of the first laser beam was set to 3000 J/m². The energy fluence of the second laser beam was set to 8100 J/m². The pulse width (radiation time) was set to 130 μsec.

The power density of reflected light of the second laser beam was sensed using an optical sensor (PD-10 Series Photovoltaic CO₂ Laser Detector from Vigo System; photosensitive unit formation material: HdCdZnTe; rise time: not more than approximately 1 nsec), based on change in the output voltage value. The sensed result by the optical sensor was output as a voltage value to the control unit. The radiation timing of the first laser beam was controlled through the control unit based on the output of the sensed result from such an optical sensor.

### EXAMPLE 2

A semiconductor thin film was fabricated using a semiconductor thin film fabrication apparatus similar to that of Example 1, provided that the control unit was implemented to modify the setting of the radiation energy of the first laser beam according to the sensed result of the optical sensor set forth above immediately before emission of the first laser beam.
as shown in FIG. 1, the substrate composite was irradiated with the second laser beam, and then irradiated with the first laser beam at an elapse of a predetermined period of time (120 μsec from the radiation initiation time of the second laser beam). In this context, the radiation energy of the first laser beam was set according to the detected result of optical sensor 22 immediately before emission of the first laser beam to control the power density. For example, when the power density of reflected light of the second laser beam is smaller than 62.3 MW/m², the energy fluence of the first laser beam was set higher than 3000 J/m².

### EXAMPLE 3

A semiconductor thin film was fabricated employing a semiconductor thin film fabrication apparatus similar to that of Example 1, provided that the optical sensor was implemented to sense change in the power density of reflected light immediately before emission of the first laser beam and that silicon has melted by the irradiation with the first laser beam. Also the control unit was implemented to control the power density of the second laser beam in accordance with the sensed result of the optical sensor immediately immediately before emission of the first laser beam.

The substrate composite was irradiated with the second laser beam, and then irradiated with the first laser beam at an elapse of a predetermined period of time (120 μsec after initiating radiation of the second laser beam), as shown in FIG. 3. In this context, the power density of the second laser beam was modulated after the precursor semiconductor thin film is melted by the first laser beam.

### COMPARATIVE EXAMPLE 1

For comparison, a semiconductor thin film was fabricated using a conventional semiconductor thin film fabrication apparatus similar to that employed in Example 1, provided that the sensing unit and control unit are absent.

The substrate composite was irradiated with the second laser beam, and then irradiated with the first laser beam at an elapse of the predetermined period of time (120 μsec from initiating radiation of the second laser beam). The energy fluence of the first laser beam was set to 3000 J/m²; the energy fluence of the second laser beam was set to 8100 J/m²; and the pulse width (radiation time) was set to 130 μsec.

TABLE 1

| | Distance of Lateral Growth (μm) |
|---|---|
| Example 1 | 17˜18 |
| Example 2 | 17˜18 |
| Example 3 | 17˜18 |
| Comparative Example 1 | 12˜18 |

The above Table 1 indicates the distance of lateral growth in semiconductor thin films produced by Examples 1-3 and Comparative Example 1 set forth above. It is appreciated from Table 1 that a crystal having the length increased significantly can be obtained in stability in accordance with the fabrication method of the present invention.

Conventionally, difference in the length of crystal for each radiation imposes the problem that, when a semiconductor device with the crystallized portion as the active layer is fabricated, the characteristics thereof, particularly the mobility, differ for each radiation. This is because the grain boundary is present with respect to the moving direction of electrons in the channel region when the length of the crystal formed is less than the desired length of crystal. When the length of crystal formed becomes smaller than the feed pitch, the crystal formed by the one preceding radiation cannot be succeeded. Therefore, the feed pitch is determined based on the shortest length of crystal formed in super lateral growth. Thus, the feed pitch had to be determined based on the shortest length of crystal that was 12 μm in the comparative example shown in Table 1. In contrast, the feed pitch can be determined based on 17 μm, that is the shortest length of crystal, according to the method of the present invention. This means that a longer pitch can be set in the present invention as compared to the conventional example, allowing a longer crystal to be obtained with fewer number of radiations.

Although the present invention has been described and illustrated in detail, it is clearly understood that the same is by way of illustration and example only and is not to be taken by way of limitation, the spirit and scope of the present invention being limited only by the terms of the appended claims.

1. A fabrication method of a semiconductor thin film including a polycrystalline semiconductor region by irradiating a precursor semiconductor thin film with at least two types of laser beams, and melting-recrystallizing said precursor semiconductor thin film,
wherein the precursor semiconductor thin film is irradiated with a predetermined reference laser beam, and a radiation initiation time or power density of a laser beam is controlled according to change in reflectance of a site irradiated with said reference laser beam.

2. The fabrication method of a semiconductor thin film according to claim 1, wherein said at least two types of laser beams comprises a first laser beam having a wavelength that can be absorbed by said precursor semiconductor thin film and energy that can melt said precursor semiconductor thin film, and a second laser beam having a wavelength and energy that can control a process of recrystallization of the molten precursor semiconductor thin film.

3. The fabrication method of a semiconductor thin film according to claim 2, wherein said reference laser beam is the second laser beam, and said radiation initiation time or power density of the first or second laser beam is controlled according to change in reflectance of the second laser beam to melting-recrystallize said precursor semiconductor thin film.

4. The fabrication method of a semiconductor thin film according to claim 2, wherein said first laser beam is emitted according to change in the power density of reflected light of said second laser beam.

5. The fabrication method of a semiconductor thin film according to claim 2, wherein the power density of said first laser beam is controlled according to change in the power density of reflected light of said second laser beam.

6. The fabrication method of a semiconductor thin film according to claim 2, wherein the power density of said second laser beam is controlled according to change in the power density of reflected light of said second laser beam.

7. The fabrication method of a semiconductor thin film according to claim 2, wherein said first laser beam has a wavelength in an ultraviolet range, and said second laser beam has a wavelength in a visible range or infrared range.

8. The fabrication method of a semiconductor thin film according to claim 2, wherein said first laser beam has a wavelength in a visible range, and said second laser beam has a wavelength in a visible range or infrared range.

9. The fabrication method of a semiconductor thin film according to claim 2, wherein said second laser beam has a wavelength in a range of 9 to 11 μm.

10. The fabrication method of a semiconductor thin film according to claim 1, wherein a crystal grown during recrystallization is grown substantially parallel to a plane of a semiconductor thin film substrate.

11. A semiconductor thin film fabrication apparatus used in the fabrication method defined in claim 1, comprising:
at least two laser light sources that can irradiate a precursor semiconductor thin film with at least two types of laser beams,
a sensing unit that can sense change in reflectance of a site of the precursor semiconductor thin film irradiated with a predetermined reference laser beam, and
a control unit controlling a radiation initiation time or power density of a laser beam according to change in reflectance at a site of said precursor semiconductor thin film irradiated with said reference laser beam.

12. The semiconductor thin film fabrication apparatus according to claim 11, wherein
said at least two laser light sources comprise a first laser light source emitting a first laser beam having a wavelength that can be absorbed by said precursor semiconductor thin film and energy that can melt said precursor semiconductor thin film, and a second laser light source emitting a second laser beam having a wavelength and energy that can control a process of recrystallization of the molten precursor semiconductor thin film,
said sensing unit can sense change in reflectance of a site irradiated with the second laser beamidentified as the reference laser beam, and
said control unit can control a radiation initiation time or power density of the first or second laser beam according to change in reflectance of a site of said precursor semiconductor thin film irradiated with the second laser beam.

13. The semiconductor thin film fabrication apparatus according to claim 12, wherein said sensing unit can sense change in a power density of reflected light of the second laser beam at a site irradiated with said second laser beam.

14. The semiconductor thin film fabrication apparatus according to claim 13, wherein said sensing unit includes an optical sensor.

15. The semiconductor thin film fabrication apparatus according to claim 12, wherein said first laser light source emits a first laser beam having a wavelength in an ultraviolet range, and said second laser light source emits a second laser beam having a wavelength in a visible range or infrared range.

16. The semiconductor thin film fabrication apparatus according to claim 12, wherein said first laser light source emits a first laser beam having a wavelength in a visible range, and said second laser light source emits a second laser beam having a wavelength in a visible range or infrared range.

17. The semiconductor thin film fabrication apparatus according to claim 12, wherein the second laser beam emitted from said second light source has a wavelength of 9 to 11 μm.

18. The semiconductor thin film fabrication apparatus according to claim 11, wherein a crystal grown during recrystallization is grown substantially parallel to a plane of a semiconductor thin film substrate.
